(19) United States
(12) Patent Application Publication
(10) Pub. No.: US 2005/0146004 A1
(43) Pub. Date: Jul. 7, 2005

(54) Semiconductor sensor device and method of producing the same

(76) Inventor: Masami Seto, Hyogo (JP)

Correspondence Address: DICKSTEIN SHAPIRO MORIN & OSHINSKY LLP, 2101 L Street, NW, Washington, DC, 20037, US

(21) Appl. No.: 11/011,425

(22) Filed: Dec. 15, 2004

(30) Foreign Application Priority Data
Dec. 16, 2003 (JP) 2003-417509

(51) Int. Cl. H01L 23/48

(52) U.S. Cl. 257/678

(57) ABSTRACT

A semiconductor sensor device is provided with a semiconductor sensor chip having a plurality of electrodes formed on a substrate surface and a semiconductor sensor, and a signal processing IC chip mounted on the semiconductor sensor chip by flip-chip bonding.

### BACKGROUND OF THE INVENTION

This application claims the benefit of a Japanese Patent Application No.2003-417509 filed Dec. 16, 2003, in the Japanese Patent Office, the disclosure of which is hereby incorporated by reference.

1. Field of the Invention

The present invention generally relates to, and more particularly to semiconductor sensor devices and methods of producing the same, and more particularly to a semiconductor sensor device which is provided with a semiconductor sensor chip having a semiconductor sensor such as a semiconductor pressure sensor, semiconductor acceleration sensor and semiconductor angular velocity sensor, and a signal processing integrated circuit (IC) chip having an amplifier for amplifying an output of the semiconductor sensor and the like, and to a method of producing such a semiconductor sensor device.

2. Description of the Related Art

Semiconductor sensors, such as semiconductor pressure sensors, semiconductor acceleration sensors and semiconductor angular velocity sensors, are popularly used in various fields. For example, such semiconductor sensors are used to measure an intake manifold pressure of an automobile engine, to measure a suction pressure of an electric vacuum cleaner for home use, to measure acceleration applied to a moving automobile in a moving or lateral direction, and to measure a hand movement in a video camera.

The semiconductor sensors may use a piezoresistance element, a piezoelectric element or an electrostatic capacitance between two electrode plates made up of a fixed electrode and a flexible electrode. For example, the semiconductor sensor using the piezoresistance element has the piezoresistance element formed on a top surface of a silicon wafer by a method similar to that employed in production of ICs. A recess is formed in a bottom surface of the silicon wafer, by etching or the like, opposite to a region in which the piezoresistance element is formed, and a diaphragm part is provided in the recess. When the diaphragm part deforms due to pressure or acceleration, this deformation causes the resistance of the piezoresistance element to change. Hence, an electric signal corresponding to the pressure or acceleration can be obtained from the piezoresistance element.

Semiconductor sensor devices provided with a semiconductor sensor chip and a signal processing IC chip have been proposed in Japanese Laid-Open Patent Applications No.8-122360 and No.10-170380, for example. The semiconductor sensor chip has a semiconductor sensor, and the signal processing IC chip has an amplifier for amplifying an output of the sensor, and the like.

In the conventional semiconductor sensor device provided with the semiconductor sensor chip and the signal processing IC chip, the semiconductor sensor chip and the signal processing IC chip are mounted on a lead frame or a wiring substrate.

FIG. 1 is a general plan view for explaining an example of the conventional semiconductor sensor device provided with a semiconductor sensor chip and a signal processing IC chip. In this conventional semiconductor sensor device shown in FIG. 1 that is provided with a semiconductor sensor chip 93 and a signal processing IC chip 95, the semiconductor sensor chip 93 and the signal processing IC chip 95 are mounted on a wiring substrate 91. Electrical connections between the semiconductor sensor chip 93 and the signal processing IC chip 95 are made directly via bonding wires 97.

As proposed in the Japanese Laid-Open Patent Application No.10-170380, the electrodes of the semiconductor sensor chip and the lead frame may be connected by bonding wires, and the lead frame may be connected to the signal processing IC chip by other bonding wires, so as to form the electrical connections between semiconductor sensor chip and the signal processing IC chip.

In the conventional semiconductor sensor devices provided with the semiconductor sensor chip and the signal processing IC chip, the bonding wires are used to form the electrical connections between the semiconductor sensor chip and the signal processing IC chip. For this reason, there were problems in that external noise easily enter the bonding wires, and that it is difficult to produce a semiconductor sensor device having a high reliability.

### SUMMARY OF THE INVENTION

Accordingly, it is a general object of the present invention to provide a novel and useful semiconductor sensor device and method of producing the same, in which the problems described above are suppressed.

Another and more specific object of the present invention is to provide a semiconductor sensor device and a method of producing the same, which can reduce external noise entering wirings between a semiconductor sensor chip and a signal processing IC chip that are provided on the semiconductor sensor device.

Still another and more specific object of the present invention is to provide a semiconductor sensor device comprising a semiconductor sensor chip having a plurality of electrodes formed on a first substrate surface and a semiconductor sensor; and a signal processing IC chip mounted on the semiconductor sensor chip by flip-chip bonding. According to the semiconductor sensor device of the present invention, the semiconductor sensor chip and the signal processing IC chip can be electrically connected without using bonding wires for the wiring. For this reason, it is possible to shorten the wiring length between the semiconductor sensor chip and the signal processing IC chip compared to the conventional case where the bonding wires are used for the wiring between the semiconductor sensor chip and the signal processing IC, to thereby reduce external noise that may enter from the wirings and accordingly improve the reliability of the output of the semiconductor sensor device. In addition, it is also possible to reduce undesirable effects caused by stray inductances and the like because the wiring between the semiconductor sensor chip and the signal processing IC is short. Moreover, a high reproducibility can be realized by use of a high-precision flip-chip bonding apparatus for the flip-chip bonding.

A further object of the present invention is to provide a method of producing a semiconductor sensor device, comprising the steps of (a) preparing a semiconductor wafer having a plurality of semiconductor sensor chips formed thereon, each of the semiconductor sensor chips having a plurality of electrodes and a semiconductor sensor formed on a substrate surface; (b) mounting signal processing IC chips on corresponding semiconductor sensor chips by flip-chip bonding; and (c) dicing the semiconductor wafer into a plurality of semiconductor sensor devices respectively made up of one signal processing IC chip and one semiconductor sensor chip. According to the method of producing the semiconductor sensor device of the present invention, the semiconductor sensor chip and the signal processing IC chip can be electrically connected without using bonding wires for the wiring. For this reason, it is possible to shorten the wiring length between the semiconductor sensor chip and the signal processing IC chip compared to the conventional case where the bonding wires are used for the wiring between the semiconductor sensor chip and the signal processing IC, to thereby reduce external noise that may enter from the wirings and accordingly improve the reliability of the output of the semiconductor sensor device. In addition, it is also possible to reduce undesirable effects caused by stray inductances and the like because the wiring between the semiconductor sensor chip and the signal processing IC is short. Moreover, a high reproducibility can be realized by use of a high-precision flip-chip bonding apparatus for the flip-chip bonding.

The method of producing the semiconductor sensor device may further comprise the steps of (g) forming an encapsulating resin at least in a vicinity of a periphery of each signal processing IC chip to encapsulate a space between each corresponding signal processing IC chip and semiconductor sensor chip, after the step (b) and before the step (c). In this case, it is possible to prevent dicing residue and cooling water from entering between the signal processing IC chip and the semiconductor sensor chip during the step (c). In addition, even though a separate member was conventionally required to cover a flexible part formation region if the flexible part of the semiconductor sensor is exposed at the semiconductor wafer surface, such a separate member is unnecessary in the present invention, and the signal processing IC chip and the encapsulating resin can also function as members for covering the flexible part formation region.

In a case where the method of producing the semiconductor sensor device further comprises the steps of (d) inspecting output characteristics of the semiconductor sensor devices after the step (b) and before the step (c); and (e) adjusting the output characteristics of the semiconductor sensor devices by adjusting resistances in the signal processing IC chips via the trimming windows based on inspection results of the step (d), and the step (g) is carried out after the step (e), the resin encapsulation of the periphery of the signal processing IC chip and the resin encapsulation of the trimming windows may be carried out simultaneously. However, when carrying out the step (g) before the step (e), the resin encapsulation of the formation region of the trimming windows should be avoided.

It is possible to provide a step of forming a dam member in the semiconductor sensor chip region of the semiconductor wafer so as to surround the semiconductor sensor formation region and/or a dam member surrounding on the signal processing IC chip so as to surround the semiconductor sensor formation region, prior to the step (g). In this case, it is possible to prevent the encapsulating resin from entering the space between the signal processing IC chip and the semiconductor sensor chip on the inner side of the dam member.

Other objects and further features of the present invention will be apparent from the following detailed description when read in conjunction with the accompanying drawings.

### BRIEF DESCRIPTION OF THE DRAWINGS

FIG. 1 is a general plan view for explaining an example of a conventional semiconductor sensor device provided with a semiconductor sensor chip and a signal processing IC chip;

FIGS. 2A and 2B respectively are a plan view and a cross sectional view generally showing a first embodiment of a semiconductor sensor device according to the present invention;

FIG. 3 is a flow chart for explaining an embodiment of a method of producing the semiconductor sensor device according to the present invention;

FIGS. 4A through 4H respectively are cross sectional views for explaining the embodiment of the method of producing the semiconductor sensor device;

FIG. 5 is a plan view showing the semiconductor sensor device at a production step S1;

FIG. 6 is a plan view showing the semiconductor sensor device at a production step S3;

FIG. 7 is a cross sectional view generally showing a second embodiment of the semiconductor sensor device according to the present invention;

FIG. 8 is a cross sectional view generally showing a third embodiment of the semiconductor sensor device according to the present invention;

FIG. 9 is a cross sectional view generally showing a fourth embodiment of the semiconductor sensor device according to the present invention;

FIG. 10 is a cross sectional view generally showing a semiconductor sensor package mounted with the semiconductor sensor device according to the present invention;

FIG. 11 is a circuit diagram showing a signal processing circuit of a signal processing IC chip that is mounted on a semiconductor sensor chip by flip-chip bonding;

FIG. 12 is a circuit diagram showing a resistor circuit for resistance adjustment and fuse elements formed in the signal processing IC chip;

FIG. 13 is a diagram showing a layout of a fuse element part;

FIG. 14 is a diagram showing a layout of a setting resistor element part; and

FIG. 15 is a diagram showing another layout of the fuse element part.

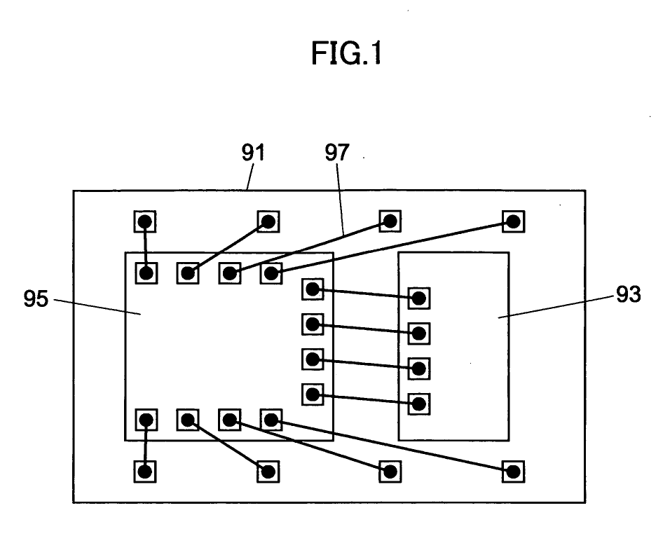

### DESCRIPTION OF THE PREFERRED EMBODIMENTS

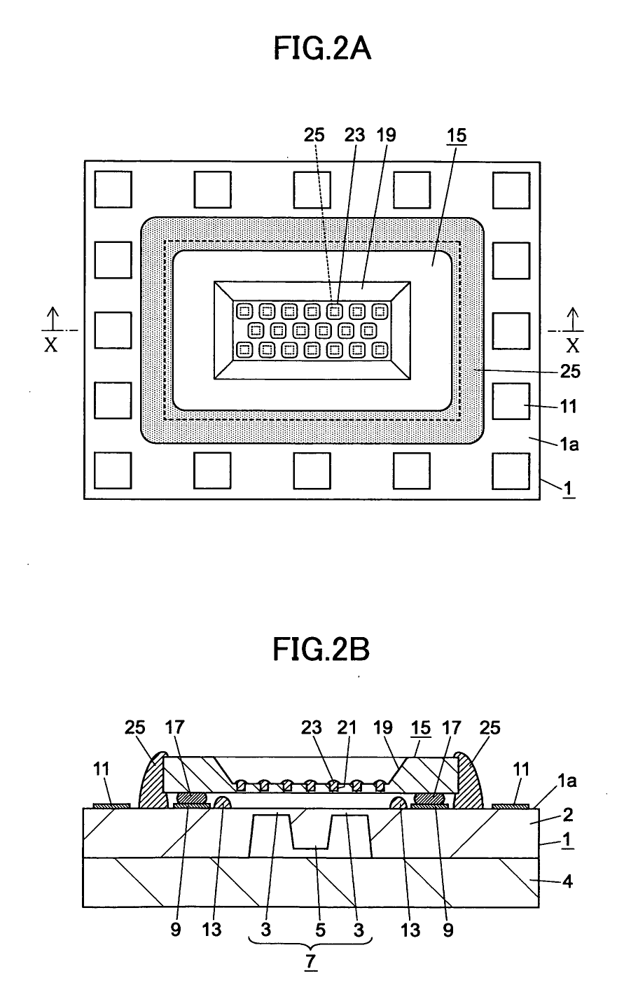

FIGS. 2A and 2B respectively are a plan view and a cross sectional view generally showing a first embodiment of a semiconductor sensor device according to the present invention. FIG. 2B shows the cross section cut along a line X-X in FIG. 2A.

A semiconductor sensor chip 1 shown in FIGS. 2A and 2B is made up of a silicon substrate 2 having a planar size of 2.5 mm×2.5 mm and a thickness of 400 μm, for example, and a glass base (or seat) 4. The silicon substrate 2 and the glass base 4 are bonded by anodic bonding, for example. A diaphragm part 3 is formed on a surface 1a of the silicon substrate 2, and a weight 5 is formed at a central portion of the diaphragm part 3. Piezoresistance elements (not shown) and electrodes (not shown) are formed on the diaphragm part 3 on the periphery of the weight 5, so as to form a piezoresistance type 3-axis semiconductor acceleration sensor (hereinafter simply referred to as a semiconductor sensor) 7. A formation region of the semiconductor sensor 7 has a planar size of 1.3 mm×0.8 mm, for example.

A plurality of pad electrodes 9 for flip-chip bonding are formed on the surface 1a of the semiconductor sensor chip 1 in a manner surrounding the semiconductor sensor 7. The flip-chip bonding refers to a process of mounting an IC chip so that the IC chip which is flipped over is directly connected to a wiring region on which the IC chip is mounted, via the wiring region or protecting connection terminals formed on the IC chip. A plurality of pad electrodes 11 for wire-bonding are formed in a peripheral region of the surface 1a on the outer side of the pad electrodes 9. A part of the pad electrodes 9 for flip-chip bonding is electrically connected to electrodes (not shown) which connect to the piezoresistance elements of the semiconductor sensor 7 via a wiring pattern (not shown). The remaining part of the pad electrodes 9 is electrically connected to the pad electrodes 11 for wire-bonding via a wiring pattern (not shown). In addition, a part of the pad electrodes 9 may be dummy pads that are formed to enable balanced mounting of a signal processing IC chip 15 which will be described later by flip-chip bonding. In this case, the dummy pads are not connected to the piezoresistance elements and the pad electrodes 11. Moreover, a part of the pad electrodes 11 for wire-bonding may be electrically connected to electrodes (not shown) that connect to the piezoresistance elements to supply power to the piezoresistance elements.

A dam member 13 is formed on the surface 1a of the semiconductor chip 1 on the inner side of the pad electrodes 9, so as to surround the semiconductor sensor 7. The dam member 13 is made of a resin having a high thixotropy, such as silicon resins and epoxy resins. In this embodiment, the dam member 13 is made of an epoxy resin CRP-3600 manufactured by Sumitomo Bakelite Kabushiki Kaisha, and has a band shape with a width of 100 μm and a height of 50 μm.

The signal processing IC chip (hereinafter simply referred to as an IC chip) 15 is mounted on the surface 1a of the semiconductor sensor chip 1 by flip-chip bonding. The IC chip 15 is arranged on the formation region of the semiconductor sensor 7 so that ball terminals (external connection terminals) 17 and the pad electrodes 9 of the semiconductor sensor chip 1 are aligned. A gap between the semiconductor sensor chip 1 and the IC chip 15 is approximately 300 μm, for example.

For example, the IC chip 15 is a wafer-level chip scale package (CSP) having elements such as transistors, resistor elements and resistor circuit for resistance adjustment formed on a main surface of a silicon substrate, and having an interlayer insulator, wiring patterns, protection layer and the ball terminals 17 formed on these elements. The IC chip 15 has a planar size of 1.3 mm×0.8 mm, and a thickness of 400 μm, for example. FIG. 2B shows a state where the silicon substrate and the protection layer are integrated. In a state where the IC chip 15 is mounted on the semiconductor sensor chip 1 by flip-chip bonding, the protection layer formed on the main surface of the silicon substrate of the IC chip 15 confronts the semiconductor sensor chip 1.

A recess 19 is formed on a bottom surface of the IC chip 15 opposite to the main surface of the silicon substrate. For example, the recess 19 is formed by subjecting the crystal surface of the silicon substrate to an anisotropic etching. The recess 19 has a tapered shape having a taper angle of approximately 55 degrees, and has an opening with a size of 550 μm×700 μm and a bottom surface with a size of 50 μm×200 μm. A plurality of trimming windows 21 are formed in the bottom surface of the recess 19 in correspondence with the positions of the plurality of fuse elements formed inside the IC chip 15. The plurality of trimming windows 21 are arranged at positions corresponding to vertexes and a center of a regular hexagon, so as to substantially achieve a maximum density, to thereby minimize the size of the opening of the recess 19 and the planar size of the trimming windows 21. An encapsulating resin 23 fills the trimming windows 21. For example, the encapsulating resin 23 is made of a resin such as silicon resins and epoxy resins. In this embodiment, the encapsulating resin 23 is made of an epoxy resin CEL-C-3140 manufactured by Hitachi Kasei Kogyo Kabushiki Kaisha.

An encapsulating resin 25 is formed on the surface 1a of the semiconductor sensor chip 1 at a position corresponding to the peripheral part of the bottom surface and the side surface of the IC chip 15 to the vicinity of the peripheral part of the IC chip 15. The encapsulating resin 25 is made of a resin having a high thixotropy, such as silicon resins and epoxy resins. The space between the semiconductor sensor chip 1 and the IC chip 15 is filled by the encapsulating resin 25. Accordingly, the semiconductor sensor 7 is covered and protected by the IC chip 15 and the encapsulating resin 25.

In this embodiment, the IC chip 15 is mounted on the semiconductor sensor chip 1 by flip-chip bonding. For this reason, the wiring length between the semiconductor sensor chip 1 and the IC chip 15 can be made short compared to the conventional case where the bonding wires are used for the wirings between the semiconductor sensor chip and the IC chip, and it is possible to reduce the external noise entering the wirings between the semiconductor sensor chip 1 and the IC chip 15. As a result, it is possible to improve the reliability of the output of the semiconductor sensor device which is made up of the semiconductor sensor chip 1 and the IC chip 15.

The IC chip 15 is provided with the resistor circuits for resistance adjustment and the fuse elements, and has the trimming windows 21 in the bottom surface of the IC chip 15 on the opposite side from the semiconductor sensor chip 1 in a state after the IC chip 15 is mounted on the semiconductor sensor chip 1. Consequently, it is possible to adjust the output characteristics of the semiconductor sensor device after the IC chip 15 is mounted on the semiconductor sensor chip 1 by the flip-chip bonding, to thereby improve the reliability of the output of the semiconductor sensor device.

The size of the semiconductor sensor device can be made small because the wafer-level CSP is used for the IC chip 15.

The recess 19 is formed in the bottom surface of the silicon substrate of the IC chip 15, and the thickness of the IC chip 15 in a region in the vicinity of the trimming windows 21 is small compared to other regions. Hence, a positional error (or alignment error) between the trimming windows 21 and the fuse elements caused by the thickness of the silicon substrate of the IC chip 15 is small, thereby making it possible to positively cut the fuse elements when cutting the fuse elements by irradiating a laser beam thereon. In this embodiment, the recess 19 is formed by carrying out the anisotropic etching with respect to the crystal surface of the silicon substrate, but it is of course possible to employ other etching techniques such as dry etching and wet etching.

Because the IC chip 15 is arranged on the semiconductor sensor 7, it is possible to reduce the planar size of the semiconductor sensor device.

Furthermore, since the encapsulating resin 25 for encapsulating the space between the semiconductor sensor chip 1 and the IC chip 15 is formed in the vicinity of the peripheral part of the IC chip 15, it is possible to protect the semiconductor sensor 7 without having to separately form a material for protecting the semiconductor sensor 7.

Moreover, because the dam member 13 is provided on the surface 1a of the semiconductor sensor chip 1 to surround the formation region of the semiconductor sensor 7, it is possible to prevent the encapsulating resin 25 which encapsulates the IC chip 15 from flowing into the formation region of the semiconductor sensor 7. The dam member 13 is particularly effective in the case of the semiconductor sensor chip 1 that is provided with the piezoresistance type semiconductor sensor 7 that has the diaphragm 3 forming a flexible part exposed at the surface of the semiconductor sensor chip 1. In a case where a resin having a high thixotropy is used for the encapsulating resin 25 which encapsulates the IC chip 15, it is possible to omit the dam member 13.

In the IC chip 15, the plurality of trimming windows 21 are arranged at positions corresponding to the vertexes and the center of the regular hexagon, so as to substantially achieve the maximum density. Thus, the planar size of the IC chip 15 can be made small, and it is possible to make the planar size of the semiconductor sensor device small.

In addition, since the trimming windows 21 are encapsulated by the encapsulating resin 23, it is possible to prevent a short-circuit in a fuse element formation region of the IC chip that would otherwise occur due to mixing of foreign particles into the trimming windows 21. It is also possible to prevent corrosion in the vicinity of the fuse element formation region due to moisture and oxidation. As a result, it is possible to improve the reliability of the IC chip 15 and the semiconductor sensor device.

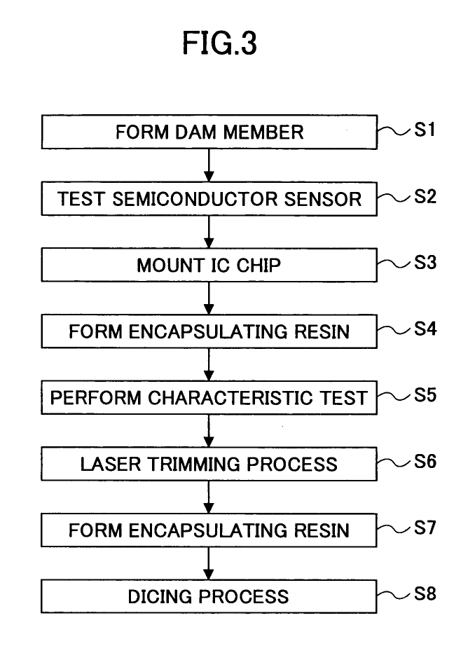

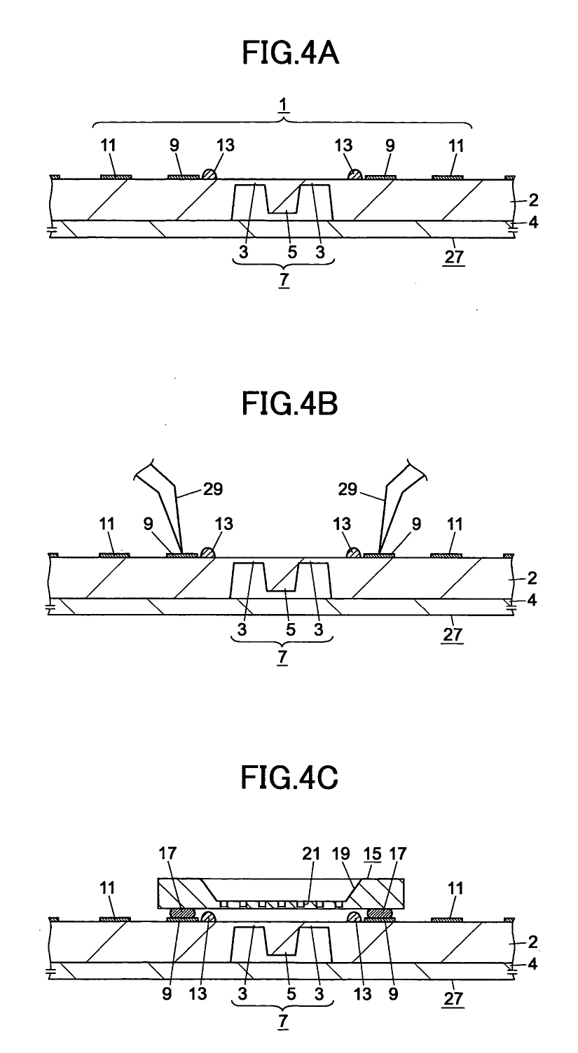

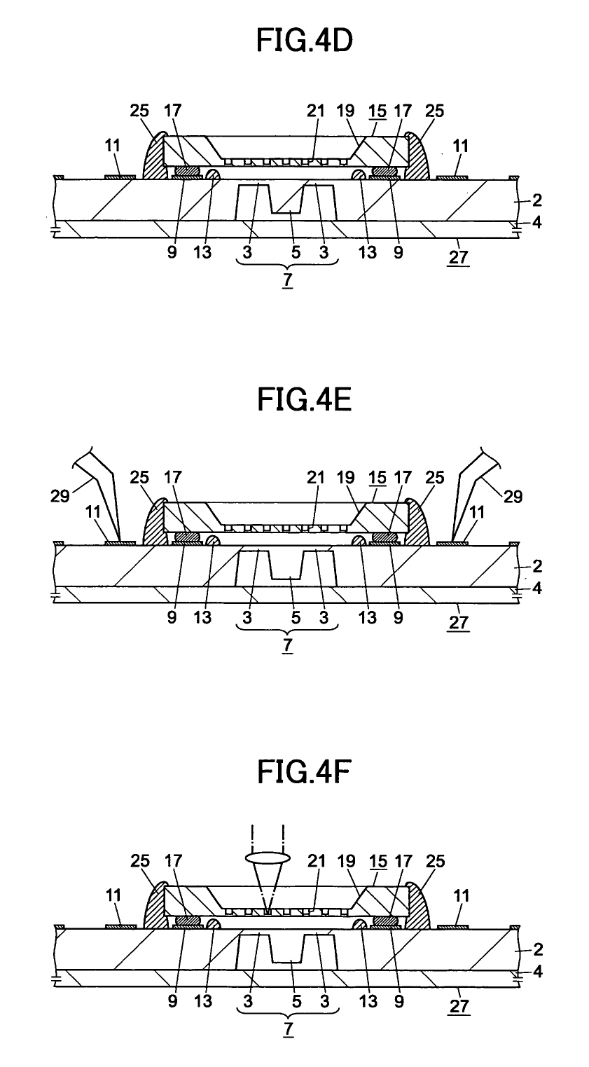

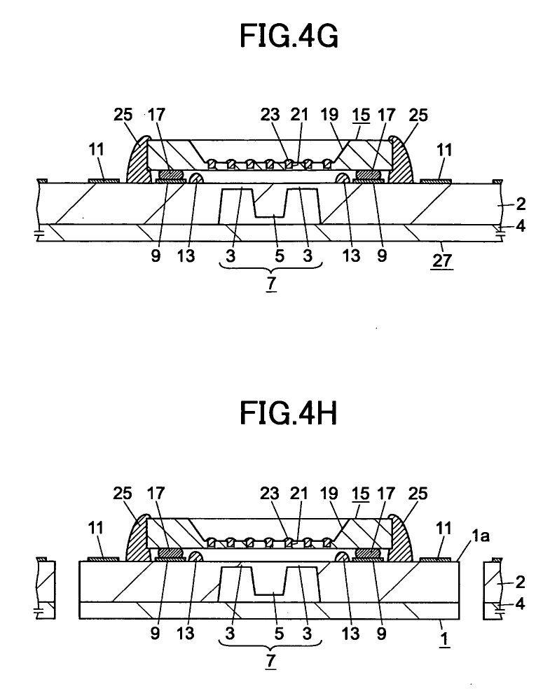

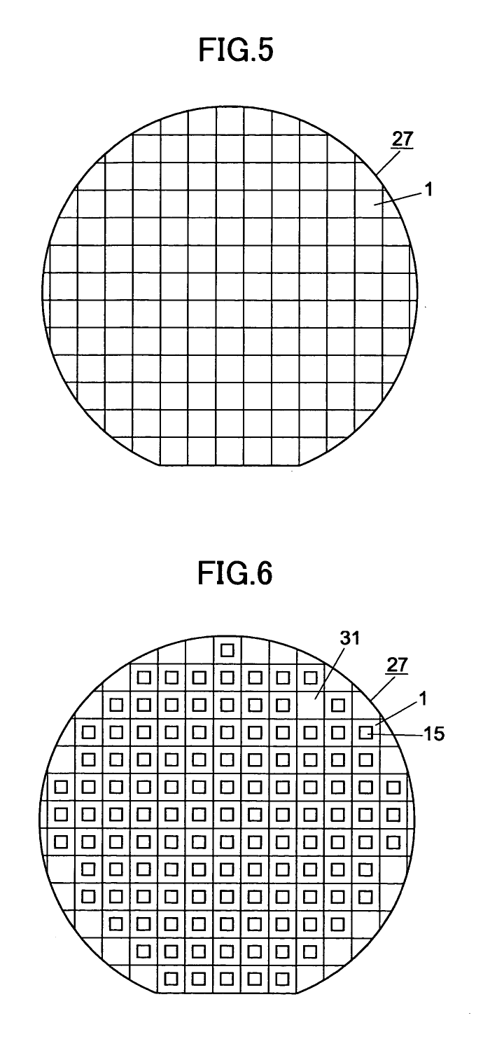

Next, a description will be given of an embodiment of a method of producing a semiconductor sensor device according to the present invention, by referring to FIGS. 3 through 6. FIG. 3 is a flow chart for explaining this embodiment of the method of producing the semiconductor sensor device according to the present invention. FIGS. 4A through 4H respectively are cross sectional views for explaining this embodiment of the method of producing the semiconductor sensor device. FIG. 5 is a plan view showing the semiconductor sensor device at a production step S1, and FIG. 6 is a plan view showing the semiconductor sensor device at a production step S3.

Step S1: A step S1 shown in FIG. 3 prepares a silicon wafer 27 made up of the silicon substrate 2 and the glass base 4 which are bonded, and having a plurality of semiconductor sensor chips 1 formed in a matrix arrangement as shown in FIG. 5. As shown in FIG. 4A, the semiconductor sensor 7, the plurality of pad electrodes 9, the plurality of pad electrodes 11 and the wiring patterns (not shown) are formed in the formation region (semiconductor sensor chip region) of each individual semiconductor sensor chip 1, where the semiconductor sensor 7 includes the diaphragm part 3, the weight 5 and the piezoresistance elements (not shown) formed in the diaphragm part 3. The dam member 13 (not shown in FIG. 5) is formed on the surface of the silicon wafer 27 (that is, the surface of the silicon substrate 2 formed with the pad electrodes 9 and 11 and the like) in a region between the semiconductor sensor 7 and the pad electrodes 9 so as to surround the semiconductor sensor 7. The dam member 13 is formed by the so-called potting which forms a resin material in a predetermined region by dispensing and thereafter curing the resin material. For example, a resin having a high thixotropy, such as silicon resins and epoxy resins, is used for the dam member 13. The dam member 13 shown in FIG. 4A is formed by using the epoxy resin CRP-3600 manufactured by Sumitomo Bakelite Kabushiki Kaisha.

Step S2: A step S2 shown in FIG. 3 carries out a test with respect to the formation region of the semiconductor sensor chip 1, in the wafer state, to determine whether or not the semiconductor sensor 7 (or semiconductor sensor chip 1) is operational. The test to determine whether or not the semiconductor sensor 7 is operational may be carried out by contacting probe needles 29 to the pad electrodes 9 that connect to the piezoresistance elements and applying a voltage to the piezoresistance elements, as shown in FIG. 4B. Examples of the test items include measurement of a diffusion resistance of the piezoresistance element and measurement (or testing) of a junction withstand voltage.

Step S3: A step S3 shown in FIG. 3 mounts the IC chip 15 that is provided with the ball terminals 17 made of solder, for example, on the formation region of the semiconductor sensor chip 1 that is judged as being satisfactory (or operational) by the test that was carried out in the step S2 to determine whether or not the semiconductor sensor 7 is operational, in correspondence with the pad electrodes 9 for flip-chip bonding, as shown in FIG. 4C. Thereafter, a thermal process is carried out for 10 seconds at 250° C., so as to melt and connect the ball terminals 17 to the pad electrodes 9. The recess 19 and the trimming windows 21 are formed in the bottom surface of the IC chip 15. As shown in FIG. 6, the IC chip 15 is not mounted on the semiconductor sensor chip 31 that is judged as being unsatisfactory (or non-operational) by the test that was carried out in the step S2 to determine whether or not the semiconductor sensor 7 is operational, so as to improve the yield.

Step S4: In a step S4 shown in FIG. 3, an encapsulating resin material is formed in the vicinity of the peripheral part of the IC chip 15 so as to encapsulate the space between the semiconductor sensor chip 1 and the IC chip 15, as shown in FIG. 4D. The encapsulating resin material is formed by the so-called potting, similarly as when forming the dam member 13. For example, a resin having a high thixotropy, such as silicon resins and epoxy resins, is used for the encapsulating resin material. In this particular case, an epoxy resin CEL-C-7400 manufactured by Hitachi Kasei Kogyo Kabushiki Kaisha was used for the encapsulating resin material. Even when the encapsulating resin material enters the space between the semiconductor sensor chip 1 and the IC chip 15, the movement of the encapsulating resin material is restricted by the dam member 13, so as to prevent the encapsulating resin material from entering the formation region of the semiconductor sensor 7. Thereafter, the silicon wafer 27 is heated to a temperature of 150° C. to 180° C. by a thermal process for 1 hour, so as to cure the encapsulating resin material in the periphery of the IC chip 15 and form the encapsulating resin 25.

Step S5: In a step S5 shown in FIG. 3, a characteristic test (or inspection) is carried out with respect to the semiconductor sensor device that is made up of a pair of the semiconductor sensor chip 1 and the IC chip 15. More particularly, electrical characteristics are measured by contacting probe needles 29 to the pad electrodes 11 as shown in FIG. 4E, and the measured electrical characteristics are stored for each semiconductor sensor device. As a result, the fuse elements to be cut via the trimming windows 21 of the IC chip 15 are determined for each semiconductor sensor device, and data indicative of the results of the characteristic test (or inspection) are stored for each semiconductor sensor device.

Step S6: In a step S6 shown in FIG. 3, a trimming process is carried out by irradiating a laser beam on predetermined fuse elements via the trimming windows 21 of the IC chip for each semiconductor sensor device as shown in FIG. 4F, based on the results of the characteristic test carried out in the step S5 with respect to each semiconductor sensor device. By adjusting the output characteristics of each semiconductor sensor device in this manner after the IC chip 15 is mounted on the semiconductor sensor chip 1 by flip-chip bonding, it becomes possible to improve the reliability of the output of each semiconductor sensor device.

Step S7: In a step S7 shown in FIG. 3, an encapsulating resin material is filled into the trimming windows 21 by the so-called potting, so as to form the encapsulating resin 23 which encapsulates the trimming windows 21 as shown in FIG. 4G. For example, silicon resins and epoxy resins may be used for the encapsulating resin material forming the encapsulating resin 23. In this particular case, an epoxy resin CEL-C-3140 manufactured by Hitachi Kasei Kogyo Kabushiki Kaisha was used for the encapsulating resin material forming the encapsulating resin 23.

In FIGS. 2B and 4G, the encapsulating resin 23 is filled to the bottom part of the trimming windows 21, however, the present invention is of course not limited to such a structure, as long as the bottom surface part of the trimming windows 21 is encapsulated by the encapsulating resin 23. In addition, the resin encapsulation need not be made for each trimming window 21, and a single resin encapsulation may be made with respect to the plurality of trimming windows 21.

Step S8: In a step S8 shown in FIG. 3, a dicing tape (not shown) is adhered on the bottom surface of the silicon wafer 27 (that is, the surface of the glass base 4 on the opposite side of the surface on which the IC chip 15 is mounted), and a dicing saw is used, for example, to dice the silicon wafer 27 into separate semiconductor sensor devices as shown in FIG. 4H. In this state, high-pressure cooling water may be sprayed on the parts where silicon wafer 27 is diced, for the purposes of cooling and/or removing dicing residue. But even in such a case where the high-pressure cooling water is sprayed, the IC chip 15 on the semiconductor sensor 7 prevents the cooling water from directly hitting the semiconductor sensor 7, to thereby prevent damage to the semiconductor sensor 7. In addition, since the formation region of the semiconductor sensor 7 is covered by the IC chip 15 and the encapsulating resin 25, it is possible to prevent the cooling water and/or the dicing residue from entering the formation region of the semiconductor sensor 7. Moreover, since the trimming windows 21 are encapsulated by the encapsulating resin 23, it is possible to prevent the cooling water and/or the dicing residue from entering the trimming windows 21.

In the embodiment of the method of producing the semiconductor sensor device described above, the step S3 carries out the thermal process to melt the ball terminals 17 before the step S4 carries out the thermal process to cure the encapsulating resin 25. However, the present invention is not limited to such, and for example, the thermal process to melt the ball terminals 17 and the thermal process to cure the encapsulating resin 25 may be carried out simultaneously.

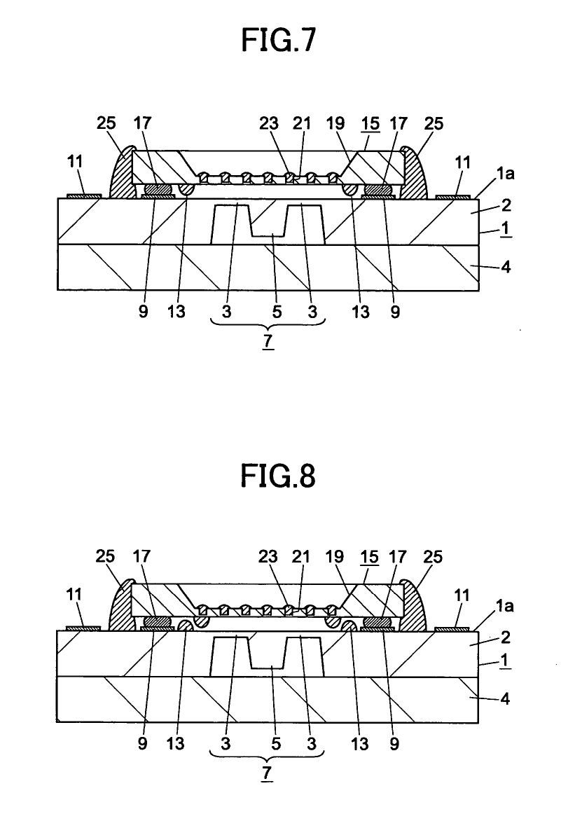

In the embodiments of the semiconductor sensor device and the method of producing the semiconductor sensor device described above, the dam member 13 is formed on the surface 1a of the semiconductor sensor chip 1 so as to prevent the encapsulating resin 25 from entering the semiconductor sensor 7. However, when a material having a high viscosity is used for the encapsulating resin 25 and this material will not move to the formation region of the semiconductor sensor 7, the dam member 13 may be omitted. In addition, a dam member 33 may be provided on the surface of the IC chip 15 confronting the semiconductor sensor chip 1 as shown in FIG. 7, instead of providing the dam member 13 on the semiconductor sensor chip 1. Moreover, both the dam member 13 and the dam member 33 may be provided as shown in FIG. 8.

FIG. 7 is a cross sectional view generally showing a second embodiment of the semiconductor sensor device according to the present invention. FIG. 8 is a cross sectional view generally showing a third embodiment of the semiconductor sensor device according to the present invention. In FIGS. 7 and 8, those parts which are the same as those corresponding parts in FIGS. 2A and 2B are designated by the same reference numerals, and a description thereof will be omitted.

In the embodiments of the semiconductor sensor device and the method of producing the semiconductor sensor device described above, the IC chip 15 which is a wafer-level CSP is mounted on the semiconductor sensor chip 1. However, the signal processing IC chip used in the present invention is of course not limited to the wafer-level CSP, and IC chips having a plurality of external connection terminals arranged in a plane, such as ball grid arrays (BGAs), fine-pitch BGAs, CSPs and bear chips, may be used.

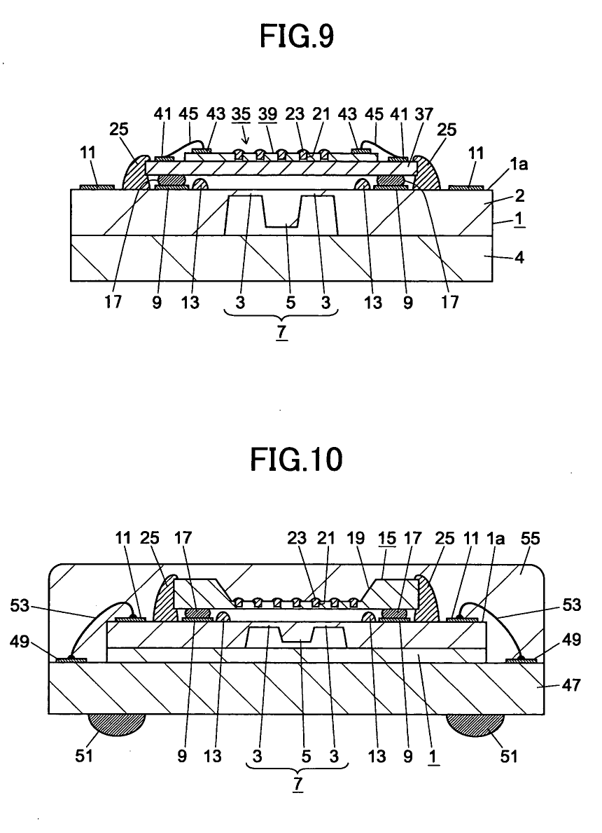

FIG. 9 is a cross sectional view generally showing a fourth embodiment of the semiconductor sensor device according to the present invention. In FIG. 9, those parts which are the same as those corresponding parts in FIGS. 2A and 2B are designated by the same reference numerals, and a description thereof will be omitted.

In FIG. 9, a BGA 35 has an IC chip 39 mounted on a wiring substrate 37, and pad electrodes 41 provided on a peripheral part of the wiring substrate 37 are electrically connected to pad electrodes 43 provided on the IC chip 39 by bonding wires 45. A resistor circuit for resistance adjustment and fuse elements are formed inside the IC chip 39, and the trimming windows 21 are formed in a top surface of the IC chip 39 in correspondence with the positions where the fuse elements are formed. The encapsulating resin 23 fills the trimming windows 21. Wiring patterns (not shown) which connect to the pad electrodes 41 are formed on the wiring substrate 37, and penetrating holes (not shown) are formed in the wiring substrate 37 in correspondence with predetermined regions of the wiring patterns. A conductive material fills the penetrating holes to form the ball terminals 17 which project from the bottom surface of the wiring substrate 37 on the opposite side from the IC chip 39. A gap between the semiconductor sensor chip 1 and the BGA 35 is approximately 500 μm, for example.

According to this embodiment using the BGA 35, it is possible to obtain the same effects as the first embodiment described above in conjunction with FIGS. 2A and 2B, except for the small chip size that is a characterizing feature of the wafer-level CSP. In this embodiment, the bonding wires 45 are used in the electrical path between the pad electrodes 9 of the semiconductor sensor chip 1 and the pad electrodes 43 of the IC chip 39. However, the length of the bonding wires 45 is short compared to the conventional case where the bonding wires are used for the wirings between the semiconductor sensor chip and the IC chip, and it is possible to reduce the external noise entering the wirings between the semiconductor sensor chip 1 and the BGA 35 (IC chip 39). As a result, it is possible to improve the reliability of the output of the semiconductor sensor device which is made up of the semiconductor sensor chip 1 and the BGA 35 (IC chip 39).

In addition, in a case where a bear chip is used for the IC chip 39, it is possible to make the gap between the semiconductor sensor chip 1 and the bear chip approximately 50 μm, for example.

This embodiment of the semiconductor sensor device shown in FIG. 9 can be produced by a method similar to the embodiment of the method of producing the semiconductor sensor device described above in conjunction with FIGS. 4A through 4H, 5 and 6, by using the BGA 35 in place of the IC chip 15. In this case, the effects obtainable by this method are similar to those obtainable by the embodiment of the method described above.

In the embodiment of the semiconductor sensor device shown in FIG. 9, the BGA 35 used does not have an encapsulating resin for packaging. However, it is of course possible to use a BGA having the encapsulating resin for packaging formed on the wiring substrate 37 including the region on which the IC chip 39 is mounted. In this case, it is desirable to form trimming windows in the encapsulating resin for packaging, in correspondence with the fuse elements.

In the embodiments described above, the signal processing IC chip that is used is provided with the resistor circuit for resistance adjustment, the fuse elements and the trimming windows, however, the present invention is not limited to such. For example, it is possible to mount on the semiconductor sensor chip, by the flip-chip bonding, a signal processing IC chip that is only provided with a signal processing circuit such as a signal amplifier circuit and is not provided with the resistor circuit for resistance adjustment.

In addition, although the embodiments described above use the semiconductor sensor chip 1 that is made up of the silicon substrate 2 and the flat glass base 4 that are bonded, the semiconductor sensor chip used in the present invention is not limited to such. For example, the semiconductor sensor chip used in the present invention may be made up of a glass base 4 having a recess or opening in correspondence with the formation region of the semiconductor sensor 7 or, made up of another silicon substrate that is bonded to the silicon substrate 2 in place of the glass base 4 or, be made up of the silicon substrate 2 and not be provided with the glass base 4.

Moreover, in the embodiments described above, the semiconductor sensor chip 1 is provided with the piezoresistance type semiconductor sensor 7 that has the diaphragm 3 forming the flexible part exposed at the surface of the semiconductor sensor chip 1, but the semiconductor sensor chip used in the present invention is not limited to such. The semiconductor sensor chip used in the present invention may not have a flexible part, such as a diaphragm and a cantilever, exposed at the surface of the semiconductor sensor chip. In addition, the semiconductor sensor chip used in the present invention may employ a piezoelectric element or an electrostatic capacitance between two electrode plates. Furthermore, the semiconductor sensor 7 is not limited to the 3-axis semiconductor acceleration sensor, and may be a semiconductor pressure sensor or a semiconductor angular velocity sensor, for example.

Next, a description will be given of a semiconductor sensor package mounted with the semiconductor sensor device according to the present invention, by referring to FIG. 10. FIG. 10 is a cross sectional view generally showing the semiconductor sensor package that is mounted with the semiconductor sensor device according to the present invention. In FIG. 10, those parts which are the same as those corresponding parts in FIGS. 2A and 2B are designated by the same reference numerals, and a description thereof will be omitted.

In FIG. 10, the semiconductor sensor device that is made up of the semiconductor sensor chip 1 and the IC chip 15 as described above in conjunction with FIGS. 2A and 2B, is mounted on a wiring substrate 47 with the semiconductor sensor chip 1 facing down. In other words, the semiconductor sensor chip 1 is mounted directly on the wiring substrate 47. However, in order to secure a moving range of the weight 5, it is possible to provide a base (or seat) or the like between the wiring substrate 47 and the semiconductor sensor chip 1.

A plurality of pad electrodes 49 are arranged in a peripheral part of the surface of the wiring substrate 47 on which the semiconductor sensor device is mounted. The number of pad electrodes 49 is the same as the number of pad electrodes 11 provided on the semiconductor sensor chip 1.

Wiring patterns (not shown) that connect to the pad electrodes 49 are formed on the wiring substrate 47, and penetrating holes (not shown) are formed in the wiring substrate 47 in correspondence with predetermined regions of the wiring patterns. A conductive material fills the penetrating holes to form ball terminals 51 which project from the bottom surface of the wiring substrate 47 on the opposite side from the semiconductor sensor chip 1.

The pad electrodes 49 of the wiring substrate 47 and the pad electrodes 11 of the semiconductor sensor chip 1 are electrically connected by bonding wires 53. Hence, the pad electrodes 11 are electrically connected to the ball terminals 51 via the bonding wires 53 and the wiring patterns on the wiring substrate 47.

An encapsulating resin 55 is formed on the entire surface of the wiring substrate 47, including a mounting region of the semiconductor sensor device. In the semiconductor sensor device, the encapsulating resin 25 is formed in the vicinity of the periphery of the IC chip 15. Hence, the space between the semiconductor sensor chip 1 and the IC chip 15 is encapsulated by the encapsulating resin 25, and the encapsulating resin material will not enter between the semiconductor sensor chip 1 and the IC chip 15 when forming the encapsulating resin 55. In addition, even when the encapsulating resin 25 is not formed, the dam member 13 is formed on the surface 1a of the semiconductor sensor chip 1 to surround the semiconductor sensor 7, and the encapsulating resin material is prevented from entering the formation region of the semiconductor sensor 7 when forming the encapsulating resin 55. Moreover, when a material having a high viscosity is used for the encapsulating resin 55 or, when the encapsulating resin 55 is formed by potting, it is possible to prevent the encapsulating resin material from entering the formation region of the semiconductor sensor 7, even if the dam 13 and/or the encapsulating resin 25 is not formed.

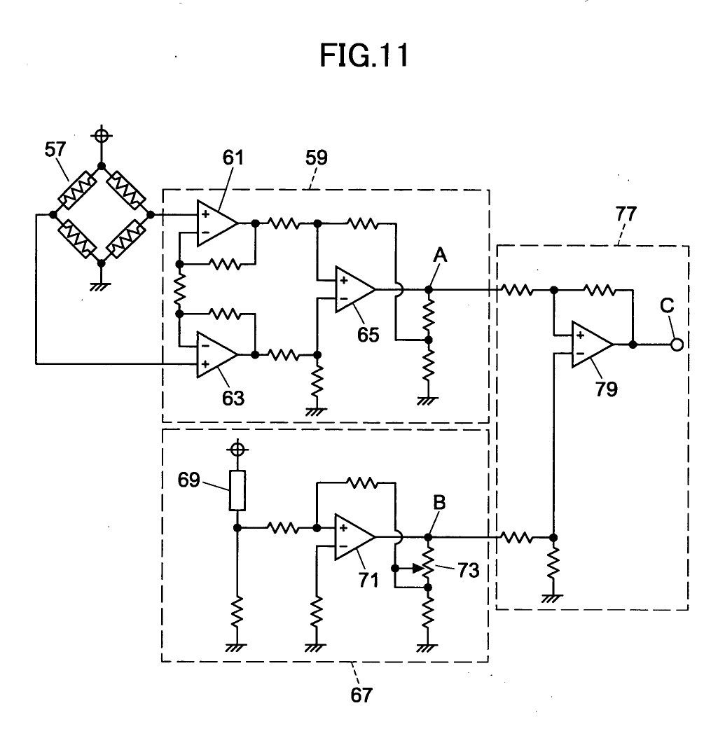

FIG. 11 is a circuit diagram showing a signal processing circuit of the signal processing IC chip 15 or 39 that is mounted on the semiconductor sensor chip 1 by flip-chip bonding.

In FIG. 11, a Wheatstone bridge circuit 57 is made up of 4 piezoresistance elements that are formed in the semiconductor sensor chip 1. A power supply potential and a ground potential are connected to a pair of confronting terminals of the Wheatstone bridge circuit 57, and potentials of a remaining pair of confronting terminals are input to a signal amplifier circuit 59 of the signal processing IC chip 15 or 39.

The signal amplifying circuit 59 amplifies signals from the piezoresistance elements forming the Wheatstone bridge circuit 57. The signal amplifying circuit 59 includes 3 differential amplifier circuits 61, 63 and 65 and a plurality of resistors which are connected as shown in FIG. 11. The signals from the Wheatstone bridge circuit 57 are supplied to non-inverting input terminals (+) of the differential amplifier circuits 61 and 63. Inverting input terminals (−) of the differential amplifier circuits 61 and 63 are mutually connected via a resistor. An output terminal of the differential amplifier circuit 61 is connected to a non-inverting input terminal of the differential amplifier circuit 65 via a resistor. An output terminal of the differential amplifier circuit 63 is connected to an inverting input terminal (−) of the differential amplifier circuit 65 via a resistor. The output of the differential amplifier circuit 61 is fed back to the inverting input terminal (−) thereof via a resistor. The output of the differential amplifier circuit 63 is fed back to the inverting input terminal (−) thereof via a resistor. Hence, the signals from the Wheatstone bridge circuit 57 are amplified by the differential amplifier circuits 61 and 63 and input to the differential amplifier circuit 65. An output of the differential amplifier circuit 65 is connected to a node The output of the differential amplifier circuit 65 is fed back to the non-inverting input terminal (+) thereof via the node A and resistors. Hence, the signals from the Wheatstone bridge circuit 57 are further amplified in the differential amplifier circuit 65 and output to the node A.

The signal processing IC chip 15 or 39 is also provided with a zero temperature compensation circuit 67 for compensating for temperature characteristics of the piezoresistance elements. The zero temperature compensation circuit 67 include a temperature sensitive element 69, a differential amplifier circuit 71, a resistor circuit 73 for resistance adjustment, fuse elements (not shown) and a plurality of resistors which are connected as shown in FIG. 11. One end of the temperature sensitive element 69 is connected to the power supply potential, and the other end of the temperature sensitive element 69 is connected to a non-inverting input terminal (+) of the differential amplifier circuit 71 via a resistor. An inverting input terminal (−) of the differential amplifier circuit 71 is connected to the ground potential via a resistor. An output of the differential amplifier circuit 71 is connected to a node B. In addition, the output of the differential amplifier circuit 71 is fed back to the non-inverting input terminal (+) thereof via the resistor circuit 73. A temperature coefficient of the temperature sensitive element 71 and a temperature characteristic of the piezoresistance elements of the semiconductor sensor chip 1 can be matched by adjusting the resistance of the resistor circuit 73. In other words, by adjusting the resistance of the resistor circuit 73, it is possible to match the temperature characteristic at the node A of the signal amplifying circuit 59 and the temperature characteristic at the node B of the zero temperature compensation circuit 67.

The signal processing IC chip 15 or 39 is also provided with a differential output circuit 77. The node A of the signal amplifying circuit 59 is connected to a non-inverting input terminal (+) of a differential amplifier circuit 79 within the differential output circuit 77. The node B of the zero temperature compensation circuit 67 is connected to an inverting input terminal (−) of the differential amplifier circuit 79. An output of the differential amplifier circuit 79 is connected to a node C. The output of the differential amplifier circuit 79 is also fed back to the non-inverting input terminal (+) thereof via a resistor. Hence, a potential that is obtained by subtracting the potential at the node B of the zero temperature compensation circuit 67 from the potential at the node A of the signal amplifying circuit 59 can be output from the node C of the differential output circuit 77, so as to substantially eliminate the temperature characteristics of the piezoresistance elements.

In the signal processing circuit shown in FIG. 11, the output of the zero temperature compensation circuit 67 is adjusted by the resistor circuit 73 for resistance adjustment. However, it is of course possible to provide a resistor circuit for resistance adjustment and a plurality of fuse elements in at least one of the signal amplifying circuit 59 and the differential output circuit 77, for the purposes of adjusting the output.

In addition, the signal processing circuit of the signal processing IC chip used in the present invention is not limited to that shown in FIG. 11, and various circuit structures may be used, including a signal processing circuit that only includes a signal amplifying circuit, for example.

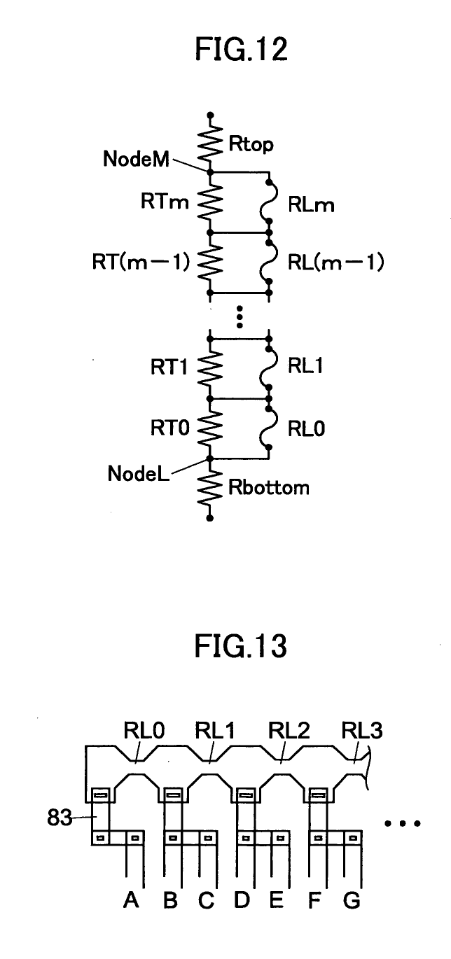

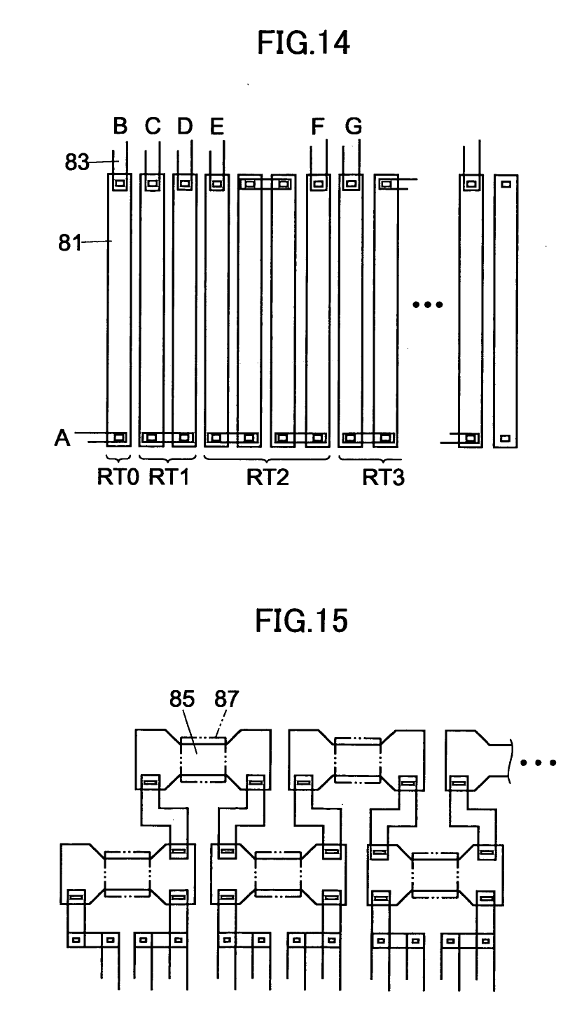

FIG. 12 is a circuit diagram showing a resistor circuit 73 for resistance adjustment and fuse elements formed in the signal processing IC chip 15 or 39. FIG. 13 is a diagram showing a layout of a fuse element part. Further, FIG. 14 is a diagram showing a layout of a setting resistor element part.

As shown in FIG. 12, the resistor circuit 73 includes a resistor element Rbottom, m+1 setting resistor elements RT0, RT1, . . . , RTm, and a resistor element Rtop that are connected in series. Fuse elements RL0, RL1, . . . , RLm are connected in parallel to the corresponding setting resistor elements RT0, RT1, . . . , RTm.

As shown in FIG. 13, the fuse elements RL0, RL1, . . . , RLm are formed by a polysilicon layer having a sheet resistance of 20 Ω to 40 Ω, for example. Although the illustration of the trimming windows is omitted in FIG. 13, the trimming windows are formed in the silicon substrate in correspondence with the formation region of each fuse element. FIG. 13 shows a case where the fuse elements and the trimming windows are arranged linearly.

The resistances of the setting resistor elements RT0, RT1, . . . , RTm are set so as to make a binary increase in an order starting from the side of the resistor element Rbottom. In other words, the resistance of a setting resistor element RTn is set in units of the resistance of the setting resistor element RT0, that is, to 2ⁿ times the unit resistance of the setting resistor element RT0.

For example, as shown in FIG. 14, a plurality of polysilicon patterns 81 made of the same material and formed in the same direction with the same dimensions are used, and the setting resistor element RTn is formed from 2ⁿ polysilicon patterns 81 by regarding 1 polysilicon pattern 81 as the unit resistance of the setting resistor element RT0. The polysilicon patterns 81 may be formed by a high-resistance polysilicon layer that is injected with P-type impurities or N-type impurities and has a sheet resistance of 100 Ω to 10 kΩ, for example.

In FIGS. 13 and 14, portions between symbols A-A, symbols B-B, symbols C-C, symbols D-D, symbols E-E, symbols F-F and symbols G-G are electrically connected by metal wirings 83. The metal wirings 83 may be made of an alloy including 98.5% aluminum, 1% silicon and 0.5% copper, and having a sheet resistance of 0.04 Ω to 0.1 Ω, for example.

In the resistor circuit 73 in which the accuracy of the ratio of the resistances of the resistor pairs is important, a plurality of unit resistor parts each made up of a pair of setting resistor element and fuse element are connected in series and arranged in a ladder layout, so as to improve the precision with which the resistor pairs are formed during the production process.

In the resistor circuit 73 having such a layout, arbitrary ones of the fuse elements RL0, RL1, . . . , RLm may be cut by irradiating a laser beam, so as to obtain a desired resistance of the series-connected resistor elements.

In the layout of the fuse elements shown in FIG. 13, the trimming windows are also arranged linearly in accordance with the fuse elements. However, if it is desirable to reduce the area of the regions in which the trimming windows are to be formed in the signal processing IC chip that is mounted on the semiconductor sensor chip by the flip-chip bonding, the trimming windows may be arranged at positions corresponding to vertexes and a center of a regular hexagon, so as to substantially achieve a maximum density. FIG. 15 is a diagram showing another layout of the fuse element part for such a case. As shown in FIG. 15, fuse elements 85 are arranged at positions corresponding to vertexes and a center of a regular hexagon, and trimming windows 87 are also arranged at the positions corresponding to the vertexes and the center of the regular hexagon in accordance with the layout of the fuse elements 85.

By employing the layout shown in FIG. 15, it is possible to reduce the planar size of the signal processing IC chip 15 or 39 and also reduce the planar size of the semiconductor sensor device. In addition, compared to the case where the trimming windows are arranged in a matrix arrangement, it is possible to increase the window size of the trimming windows without substantially increasing the size of the region in which the trimming windows are arranged. Hence, the layout shown in FIG. 15 is particularly effective when the signal processing IC chip is a wafer-level CSP having a small planar size and the trimming windows formed in the semiconductor substrate.

Further, the present invention is not limited to these embodiments, but various variations and modifications may be made without departing from the scope of the present invention.

1. A semiconductor sensor device comprising:
a semiconductor sensor chip having a plurality of electrodes formed on a substrate surface and a semiconductor sensor; and
a signal processing IC chip mounted on the semiconductor sensor chip by flip-chip bonding.

2. The semiconductor sensor device as claimed in claim 1, wherein the signal processing IC chip comprises:
a resistor circuit for resistance adjustment;
a plurality of fuse elements; and
a plurality of trimming windows formed in a surface of the signal processing IC chip on an opposite side from the semiconductor sensor chip.

3. The semiconductor sensor device as claimed in claim 1, wherein the signal processing IC chip is disposed on the semiconductor sensor.

4. The semiconductor sensor device as claimed in claim 3, further comprising:
an encapsulating resin encapsulating a space between the signal processing IC chip and the semiconductor sensor chip at least in a vicinity of a periphery of the signal processing IC chip.

5. The semiconductor sensor device as claimed in claim 3, further comprising:
a dam member formed on at least one of confronting surfaces of the semiconductor sensor chip and the signal processing IC chip, so as to surround a periphery of a formation region of the semiconductor sensor.

6. The semiconductor sensor device as claimed in claim 2, wherein the signal processing IC chip is made of a wafer-level chip scale package (CSP) having elements, a protection layer and external connection terminals formed on a main surface of a semiconductor substrate, and the trimming windows are formed in the semiconductor substrate.

7. The semiconductor sensor device as claimed in claim 6, wherein a thickness of the semiconductor substrate in a vicinity of a region of the trimming windows is smaller than that of other regions.

8. The semiconductor sensor device as claimed in claim 7, wherein the semiconductor substrate has a recess, and the trimming windows are formed within the recess, so that the thickness of the semiconductor substrate in the vicinity of the region of the trimming windows is smaller than that of the other regions.

9. The semiconductor sensor device as claimed in claim 2, wherein the trimming windows are arranged at positions corresponding to vertexes and a center of a regular hexagon, so as to substantially achieve a maximum density.

10. The semiconductor sensor device as claimed in claim 2, wherein:
the semiconductor sensor chip comprises a piezoresistance type sensor having piezoresistance elements as detection elements; and
the signal processing IC chip comprises a signal amplifying circuit configured to amplify signals from the piezoresistance type sensor, a zero temperature compensation circuit configured to compensate for temperature characteristics of the piezoresistance type sensor, and a temperature characteristic elimination circuit configured to output a difference of an output of the signal amplifying circuit and an output of the zero temperature compensation circuit,
said zero temperature compensation circuit including a temperature sensitive element, a resistor circuit and a plurality of fuse elements.

11. A method of producing a semiconductor sensor device, comprising the steps of:
(a) preparing a semiconductor wafer having a plurality of semiconductor sensor chips formed thereon, each of the semiconductor sensor chips having a plurality of electrodes and a semiconductor sensor formed on a substrate surface;
(b) mounting signal processing IC chips in regions of semiconductor sensor chips by flip-chip bonding; and
(c) dicing the semiconductor wafer into a plurality of semiconductor sensor devices respectively made up of one signal processing IC chip and one semiconductor sensor chip.

12. The method of producing the semiconductor sensor device as claimed in claim 11, wherein the step (b) uses signal processing IC chips respectively comprising a resistor circuit for resistance adjustment, a plurality of fuse elements, and a plurality of trimming windows formed in a surface of the signal processing IC chip on an opposite side from the semiconductor sensor chip, and further comprising the steps of:
(d) inspecting output characteristics of the semiconductor sensor devices after the step (b) and before the step (c); and
(e) adjusting the output characteristics of the semiconductor sensor devices by adjusting resistances in the signal processing IC chips via the trimming windows based on inspection results of the step (d).

13. The method of producing the semiconductor sensor device as claimed in claim 12, further comprising the steps of:
(f) encapsulating the trimming windows after the step (e) and before the step (c).

14. The method of producing the semiconductor sensor device as claimed in claim 11, wherein the step (b) arranges the signal processing IC chips on the semiconductor sensors and mounts the signal processing IC chips in the regions of the semiconductor sensor chips.

15. The method of producing the semiconductor sensor device as claimed in claim 14, further comprising the steps of:
(g) forming an encapsulating resin at least in a vicinity of a periphery of each signal processing IC chip to encapsulate a space between each corresponding signal processing IC chip and semiconductor sensor chip, after the step (b) and before the step (c).

16. The method of producing the semiconductor sensor device as claimed in claim 15, further comprising the steps of:
(h) forming a dam member in the region of each semiconductor sensor chip on the semiconductor wafer so as to surround a formation region of a corresponding semiconductor sensor, before the step (b).

17. The method of producing the semiconductor sensor device as claimed in claim 14, wherein the step (b) uses signal processing IC chips respectively comprising a dam member formed in the region of a corresponding semiconductor sensor chip so as to surround a formation region of a corresponding semiconductor sensor.

18. The method of producing the semiconductor sensor device as claimed in claim 11, further comprising the steps of:
(i) testing each semiconductor sensor to determine whether or not each semiconductor sensor chip on the semiconductor wafer is operational, before the step (b),
wherein the step (b) mounts no signal processing IC chip in the region of the semiconductor sensor chip that is judged as being non-operational by the step (i).
